(19) United States
(12) Patent Application Publication
(10) Pub. No.: US 2021/0036439 A1
(43) Pub. Date: Feb. 4, 2021

(54) WIRE HARNESS

(71) Applicant: SUMITOMO WIRING SYSTEMS, LTD., Yokkaichi-shi, Mie (JP)

(72) Inventors: Hiroki MATSUYAMA, Yokkaichi-shi (JP); Hirokazu NAKAI, Yokkaichi-shi (JP)

(73) Assignee: SUMITOMO WIRING SYSTEMS, LTD., Yokkaichi-shi, Mie (JP)

(21) Appl. No.: 16/982,362

(22) PCT Filed: Mar. 12, 2019
(86) PCT No.: PCT/JP2019/009858

§ 371 Date: Sep. 18, 2020

(30) Foreign Application Priority Data
Mar. 30, 2018 (JP) 2018-069927

(51) Int. Cl. H01R 4/18; H01B 9/02

(52) U.S. Cl. CPC H01R 4/18; H01R 11/12; H01B 9/024

(57) ABSTRACT

A wire harness including: a plurality of shielded conductive paths including a plurality of wire bundles composed of a plurality of wires, and a plurality of shields that are composed of braided wires in which electrically conductive wires are braided into tubular shapes, and that individually encase the plurality of wire bundles; and a connector into which the plurality of shielded conductive paths are inserted, the connector being configured to be attached to a housing of a device, wherein the shields include tubular bodies that encase the wire bundles, and separated portions that extend separated from the wire bundles at portions of the bodies on terminal end sides of the wire bundles with respect to the connector, and the separated portions of the plurality of shields are grouped together.

### BACKGROUND

The present disclosure relates to a wire harness.

Conventionally, wire harnesses for use in automobiles for example include a plurality of wire bundles made from a plurality of wires, and a connector that is to have the wire bundles inserted therein and that is to be attached to the housing of a device (e.g., JP 2012-84275A).

The wire harness described in JP 2012-84275A includes a shield member that is made from a braided wire in which electrically conductive wire strands are braided together, and shields against electromagnetic noise by encasing the plurality of wire bundles.

### SUMMARY

The wire harness described in JP 2012-84275A requires a shield member that includes a plurality of branched portions that branch along branching paths of the wire harness. However, a problem with a shielding member such as that described above is that forming the shielding member by braiding together wire strands is technologically difficult and the manufacturing process thereof is complex.

An exemplary aspect of the disclosure provides a wire harness with which it is possible to adequately shield branching paths with a simple configuration.

A wire harness according to an exemplary aspects includes: a plurality of shielded conductive paths including a plurality of wire bundles composed of a plurality of wires, and a plurality of shields that are composed of braided wires in which electrically conductive wires are braided into tubular shapes, and that individually encase the plurality of wire bundles; and a connector into which the plurality of shielded conductive paths are inserted, the connector being configured to be attached to a housing of a device, wherein the shields include tubular bodies that encase the wire bundles, and separated portions that extend separated from the wire bundles at portions of the bodies on the terminal end sides of the wire bundles with respect to the connector, and the separated portions of the plurality of shields are grouped together.

With the configuration described above, the plurality of shielded conductive paths are inserted into the connector. Also, the shields include separated portions that extend separated from the wire bundles on the terminal end sides of the wire bundles with respect to the connector, that is, inside of the housing. The separated portions are grouped together. For this reason, it is possible to suppress the occurrence of the wires being exposed from the shields outside of the housing of the device to which the connector is to be attached. Also, it is possible to collectively ground the shields by fixing the separated portions of the shields to predetermined locations in the housing.

Here, the wires are exposed from the shields inside the housing. However, the housing itself has a shielding function and thus ensures shielding. In this way, with the configuration described above, it is possible to adequately shield the branching paths of the wire harness without using shields having branched portions.

In the wire harness described above, it is preferable that a terminal is fixed to the separated portions.

With this configuration, it is possible to easily fix the separated portions to predetermined locations in the housing via the terminal. Thus, it is possible to easily ground the shields.

In the wire harness described above, it is preferable that the separated portions are press-fixed to the terminal in a pre-molded state.

With this configuration, the task of fixing the separated portions of the shields and the terminal to each other becomes much easier.

In the wire harness described above, it is preferable that the separated portions are provided inside of the housing, and the separated portions of the plurality of shields that are grouped together are grounded in the housing.

With the present disclosure, it is possible to adequately shield branching paths with a simple configuration.

### BRIEF DESCRIPTION OF THE DRAWINGS

FIG. 1 is a plan view showing a wire harness in a state of being routed between devices, in an embodiment of the wire harness.

FIG. 2 is a plan view showing an enlarged view focused on a connector, in the wire harness of the embodiment.

FIG. 3 is an enlarged perspective view focused on a press-fixed portion of the separated portions of the shield members and the terminal member, in a wire harness of a modified example.

FIG. 4 is an exploded perspective view showing a separated portion of the shield member and a barrel portion of the terminal member before being crimped in FIG. 3 separated from each other.

### DETAILED DESCRIPTION OF EMBODIMENTS

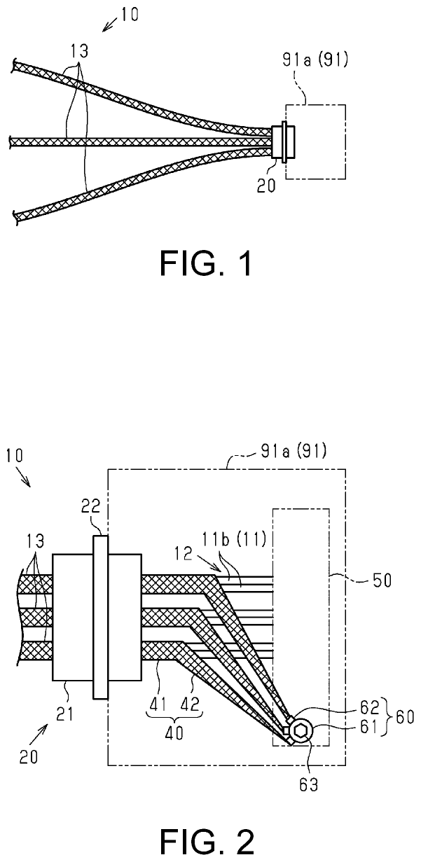

The following is a description of an embodiment of a wire harness with reference to FIG. 1 and FIG. 2.

As shown in FIG. 1, a wire harness 10 is routed in a hybrid vehicle or an electric automobile for example, and electrically connects devices to each other.

As shown in FIG. 1 and FIG. 2, the wire harness 10 includes a plurality (three in the present embodiment) of shielded conductive paths 13 that shield against electromagnetic noise, and a connector 20 that is to be attached to a housing 91a of a device 91.

The shielded conductive paths 13, which are led out of the connector 20, are branched and are individually connected to devices (not shown).

### Shielded Conductive Paths 13

As shown in FIG. 2, the shielded conductive paths 13 are constituted by wire bundles 12 that are each made from a plurality (two in the present embodiment) of wires 11, and shield members 40 (shields) that encase the wire bundles 12.

Each of the wires 11 include a core wire (not shown) and an insulating covering 11b that covers the outer periphery of the core wire. Each of the wires 11 is a non-shielded wire that does not have a shielded structure.

The core wire is, for example, a stranded wire that is formed by stranding together a plurality of metal strands that are made of a copper alloy. The terminal ends of the core wires of the wires 11 are fixed to a terminal (not shown) that is to be connected to one or more electrical elements of the device 91 in the housing 91a.

The insulating covering 11b is made from an electrically insulating synthetic resin material, and has a cylindrical shape.

The shield members 40 are made from braided wires that are constituted by electrically conductive wire strands that are made from an aluminum alloy or the like and have been braided into a tubular shape.

As shown in FIG. 2, the plurality of shielded conductive paths 13 are inserted into the connector 20. Toward the terminal end sides of the wire bundles 12 with respect to the connector 20, that is, inside of the housing 91a, the wire bundles 12 are exposed to the outside from the insides of the corresponding shield members 40 through gaps between the wire strands that constitute the side walls of the corresponding shield members 40. Note that the gaps described above are formed by spreading out the gaps between the wire strands.

The shield members 40 include tubular body portions 41 (tubular bodies) that encase the wire bundles 12, and separated portions 42 that extend separated from the wire bundles 12 without encasing the wire bundles 12 in the housing 91a.

### Connector 20

As shown in FIG. 2, the connector 20 includes a tubular portion 21, and a flange 22 that protrudes outward from the periphery of the tubular portion 21. The flange 22 is provided in an intermediate portion of the tubular portion 21 in the axial direction thereof. The flange 22 is provided with an attachment hole (not shown) for attachment to the housing 91a. The connector 20 is formed from a metal material such as an aluminum alloy.

### Terminal Member 60

As shown in FIG. 2, a terminal member 60 (terminal) called an open-barrel terminal is fixed to the separated portions 42 of the shield members 40. The terminal member 60 includes a base portion 61 that has a screw-hole (not shown), and barrel portions 62 that extend from the base portion 61. The terminal member 60 is made from an electrically conductive metal material such as an aluminum alloy. The end portions of the separated portions 42 of the shield members 40, which are respectively consolidated into columnar shapes in advance, are press-fixed to the terminal member 60 by the barrel portions 62, which are crimped into cylindrical shapes.

The terminal members 60 are fixed in a state of overlapping each other by fastening a screw 63, which is inserted into the screw hole in the base portion 61, to a bus bar 50 that is provided in the metal housing 91a.

Accordingly, the end portions of the separated portions 42 of the shield members 40 are grouped together via the terminal members 60.

Note that it is preferable that the terminal members 60 are arranged such that the barrel portions 62 do not overlap each other.

Next, the actions and effects of the present embodiment will be described.

(1) The shield members 40 include the tubular body portions 41 that encase the wire bundles 12, and the separated portions 42 that extend separated from the wire bundles 12 at the portions on the terminal end side of the wire bundles 12 with respect to the connector 20, that is, at the portions inside of the housing 91a. The separated portions 42 are grouped together.

With this configuration, the plurality of shielded conductive paths 13 are inserted into the connector 20. Also, the shield members 40 include the separated portions 42 that extend separated from the wire bundles 12 in the housing 91a. The plurality of separated portions 42 are grouped together.

Thus, it is possible to suppress the occurrence of the wires 11 being exposed from the shield members 40 outside of the housing 91a of the device 91 to which the connector 20 is to be attached. Also, it is possible to collectively ground the shield members 40 by fixing the separated portions 42 of the shield members 40 to the bus bar 50 in the housing 91a.

Here, the wires 11 are exposed from the shield members 40 in the housing 91a. However, the housing 91a itself has a shielding function and thus ensures shielding. In this way, with the configuration described above, it is possible to adequately shield the branching paths of the wire harness 10 without using shielding members having branched portions. Thus, it is possible to adequately shield the branching paths of the wire harness 10 with a simple configuration.

(2) The terminal member 60 is fixed to the separated portions 42.

With this configuration, the separated portions 42 can be fixed to the bus bar 50 in the housing 91a via the terminal member 60. Thus, it is possible to easily ground the shield members 40.

(3) The separated portions 42 are press-fixed to the terminal member 60 in a state of being formed into columnar shapes in advance.

With this configuration, the task of fixing the separated portions 42 and the terminal member 60 to each other becomes much easier.

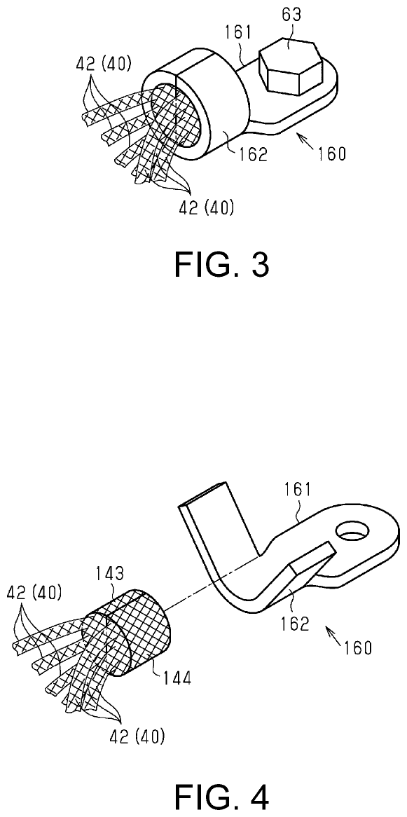

The present embodiment can be implemented with the following modifications. The present embodiment and the following modified examples thereof can be implemented in combination with each other as long as there are no technological contradictions.
The number of shielded conductive paths 13 that constitute the wire harness 10 can be changed to any number.
The number of wires 11 that constitute one shielded conductive path 13 can be changed to three or more.
As shown in FIG. 3 and FIG. 4, for example, a configuration is also possible in which a molded body 143 that is molded into a half-columnar shape by grouping together the separated portions 42 of three shield members 40 out of six shield members 40 in advance, and a molded body 144 that is molded into a half-columnar shape by grouping together the separated portions 42 of the three remaining shield members 40 in advance, may also be brought into contact with each other to form a columnar shape, and press-fixed to a terminal member 160. The terminal member 160 includes a base portion 161 that has a screw-hole into which the screw 63 is inserted, and a barrel portion 162 that is extended from the base portion 161, and the columnar-shaped separated portions 42 are press-fixed by the barrel portion 162 being crimped into a cylindrical shape.

With this configuration, the molded body 143 that is made from a portion of the separated portions 42 of the shield members 40, and the molded body 144 that is made from the remaining separated portions 42 are brought into contact with each other to form a columnar shape, and therefore the task of press-fixing the separated portions 42 of the shield members 40 to the terminal member 160 becomes much easier. Note that the shape of the molded bodies 143 and 144 is not limited to being a half-columnar shape, and may be changed to any shape, such as a triangular prism shape.
The mode with which the separated portions 42 of the shield members 40 are fixed to the terminal member 60 is not limited to press-fixing. Other fixing modes, such as soldering or welding, can also be employed.
It is also possible to group the separated portions 42 of the shield members 40 into a tabular shape beforehand and use a metal crimping ring or the like to fasten and fix the separated portions 42 in a state of being aligned on an outer surface of the bus bar 50. Also, in this case, the grouped separated portions 42 may also be directly fixed to the bus bar 50 through soldering or welding.
The terminal member 60 is not limited to being attached to the bus bar 50 as long as the terminal member 60 is inside of the housing.

The present disclosure encompasses the following implementation examples. Reference numerals have been assigned to the components of the embodiments to aid in understanding, but not to indicate limitation.

### [Supplementary Note 1]

The wire harness (10) according to several implementation examples is constituted by a metal connector (20) that includes a tubular portion (21) and a flange (21) that expands radially outward from the tubular portion (21), and a plurality of shielded conductive paths (13) that pass through the connector (20), wherein the shielded conductive paths (13) include wire bundles (12) made from a plurality of wires (11), and a plurality of flexible shield members (40) that cover the wire bundles (12) and are each an electrically conductive braided tube, the plurality of wires (11) of the plurality of shielded conductive paths (13) are configured to be electrically connected to one or more electrical elements of an electrical device (91) in a housing (91a) of the electrical device (91), the flexible shield members (40) pass through the connector (20) in a state of covering the corresponding wire bundles (12), the flexible shield members (40) include long separated leading end portions (42) that are drawn out away from the outer surfaces of the corresponding wires (11) in the housing (91a) of the electrical device (91), and the separated leading end portions (42) of the plurality of the flexible shield members (40) are connected to ground terminals (60) that are different from the one or more electrical elements in the housing (91a) of the electrical device (91).

### [Supplementary Note 2]

In several implementation examples, the connector (20) is configured so as to be attached to the housing (91a) from the outside of the housing (91a) of the electrical device (91), and each of the plurality of the wires (11) of the shielded conductive paths (13) is configured to include a long non-shielded leading end portion that is not covered by the flexible shield member (40) in the housing (91a) of the electrical device (91).

### [Supplementary Note 3]

In several implementation examples, the ground terminal (60) is a single ground terminal (60) that includes a plurality of barrel portions (62), and the separated leading end portions (42) of the plurality of flexible shield members (40) are fixedly and electrically connected to the plurality of barrel portions (62) of the single ground terminal (60).

### [Supplementary Note 4]

In several implementation examples, the single ground terminal (60) is fixedly and electrically connected to a bus bar (50) in the housing (91a) of the electrical device (91).

It will be apparent to those skilled in the art that the present disclosure may be embodied in other specific forms without departing from the technical idea thereof. For example, some of the components described in the embodiment (or one or more modes thereof) may be omitted or several components may be combined. The scope of the disclosure should be established with the full range of equivalency to which the claims are entitled, with reference to the appended claims.

1. A wire harness comprising:
a plurality of shielded conductive paths including a plurality of wire bundles composed of a plurality of wires, and a plurality of shields that are composed of braided wires in which electrically conductive wires are braided into tubular shapes, and that individually encase the plurality of wire bundles; and
a connector into which the plurality of shielded conductive paths are inserted, the connector being configured to be attached to a housing of a device, wherein
the shields include tubular bodies that encase the wire bundles, and separated portions that extend separated from the wire bundles at portions of the bodies on terminal end sides of the wire bundles with respect to the connector, and
the separated portions of the plurality of shields are grouped together.

2. The wire harness according to claim 1, wherein
a terminal is fixed to the separated portions.

3. The wire harness according to claim 2, wherein
the separated portions are press-fixed to the terminal in a pre-molded state.

4. The wire harness according to claim 1, wherein
the separated portions are provided inside of the housing, and
the separated portions of the plurality of shields that are grouped together are grounded in the housing.
